(19) United States
(12) Patent Application Publication
(10) Pub. No.: US 2025/0017346 A1
(43) Pub. Date: Jan. 16, 2025

(54) DEVICE FOR THE AUTOMATIC CONTROL OF A HAIR DRYER

(71) Applicant: DBL COMPANY S.R.L., Sant’Antimo (Napoli) (IT)

(72) Inventor: Luciano DI BIASE, Sant’Antimo (Napoli) (IT)

(73) Assignee: DBL COMPANY S.R.L., Sant’Antimo (Napoli) (IT)

(21) Appl. No.: 18/714,373

(22) PCT Filed: Nov. 30, 2021
(86) PCT No.: PCT/IB2021/061111

§ 371 Date: May 29, 2024

(51) Int. Cl. A45D 20/12; A45F 5/02

(52) U.S. Cl. CPC A45D 20/12; A45F 5/021; A45D 2020/128

(57) ABSTRACT

A device for the automatic control of a hair dryer having a wearable element provided with a support for the removable engagement with the hair dryer. The device includes a first control element which can be coupled with the wearable element, and a second control element which can be coupled with the hair dryer which cooperate to automatically switch the hair dryer on and off.

### FIELD OF THE INVENTION

The present invention relates to a device for the automatic control of a hair dryer, more particularly a device designed to reduce the energy consumption of the hair dryer while simultaneously optimising the experience of use by an operator.

### STATE OF THE PRIOR ART

When treating the hair of a customer, besides drying with a hair dryer, a professional hairdresser can carry out several particular treatments on the hair, for example dyeing or decolouration, straightening or curling, trichological treatments by applying specific substances, etc. Such particular treatments often require the use of specific tools such as heating plates, hair irons, combs, etc. The hairdresser will therefore have to alternate the use of the hair dryer with that of other tools, and will therefore be forced to lay down the hair dryer to free the hands thereof. This operation can be inconvenient and complicated mainly for two reasons. The first lies in the fact that the hairdresser does not always have—in the vicinity thereof—a support suitable to place the hair dryer, and therefore will either have to waste time moving away from the customer to find one, or take the risk of placing the hair dryer nearby but with the risk of interfering with the normal movement of the user, limiting the mobility thereof.

The second reason stems from the fact that in order to reduce the energy consumption and noise of the hair dryer when not in use, the hairdresser must switch it off whenever he/she needs to place it down and switch it on whenever he/she needs to use the hair dryer again. Besides being uncomfortable for the operator, switching the hair dryer on and off manually could also delete the operation settings of the hair dryer. It is actually known that an excellent hair treatment method provides for specific adjustments of the temperature and air flow-rate of the hair dryer, for example depending on the characteristics of the hair of each customer, on the particular required treatment and on the experience of the hairdresser.

Therefore, there arises the need for a device for the automatic control of a hair dryer that allows to overcome the aforementioned drawbacks.

### SUMMARY OF THE INVENTION

In order to achieve this object, the present invention relates to a device for the automatic control of a hair dryer whose primary characteristic lies in the fact that it comprises a wearable element provided with a support for the removable engagement with the hair dryer, and in that it comprises a first control element which can be coupled with the wearable element, and a second control element which can be coupled with the hair dryer, the second control element being designed to switch off the hair dryer when arranged in proximity of the first control element, and to switch off the hair dryer when arranged far from the first control element.

Thanks to this solution idea, when treating the hair of a customer, the hairdresser may lay the hair dryer down, whenever there arises s the need, in a comfortable and safe place without having to switch it off manually, and may remove the hair dryer from the support whenever there arises the need without having to switch it on manually.

Therefore, the device according to the invention allows to improve the comfort of use of the hair dryer by the operator simultaneously ensuring a decrease in the energy consumption thereof.

In a preferred embodiment of the device according to the invention, the aforementioned first control element is a magnet and the aforementioned second control element is a magnetometer sensor, or vice versa.

This allows to provide for a control system of the hair dryer without rotary elements, ensuring a greater reliability of the hair dryer, simplifying the water-proof capacity and cleanliness thereof, and extending the time of use thereof.

According to a further aspect of the invention, the wearable element comprises a belt and the support includes a waist bag carried by the belt.

In a further embodiment of the device according to the invention, the hair dryer comprises a pair of buttons for setting a hair drying program by adjusting respectively the flow rate and temperature of the air dispensed by the hair dryer, and a CPU designed to store the set drying program and to maintain such program each time the hair dryer is switched off and on.

This allows the hairdresser to comfortably set the hair drying program that most suits the needs of the customer and the hair dryer will store and maintain such program during the entire treatment.

### BRIEF DESCRIPTION OF THE DRAWINGS

Further characteristics of the invention will be apparent from the following detailed description, with reference to the attached drawings, provided purely by way of non-limiting example, wherein:

FIG. 1 is a perspective view of a hair dryer provided with a part of the device according to the invention,

FIG. 2 is a perspective view of the hair dryer and of the wearable element according to the invention,

FIG. 3 is a perspective view of the device according to the invention in a use configuration thereof.

### DETAILED DESCRIPTION OF THE INVENTION

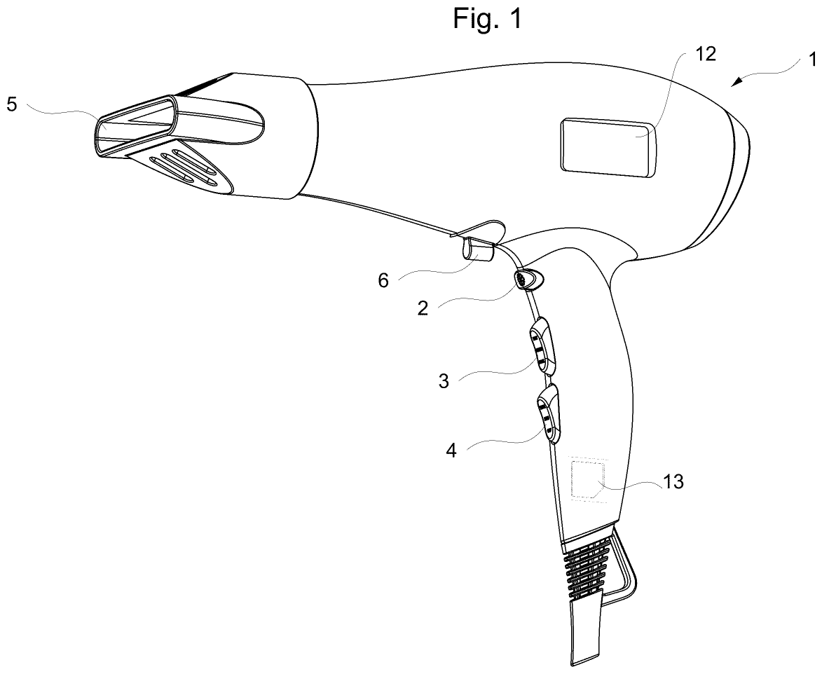

Initially with reference to FIG. 1, a hair dryer consisting of a generally conventional equipment provided with an ON-OFF button 2 for switching on and off as well as a pair of multi-position buttons 3,4 for setting various combinations of the flow rate and temperature of the air dispensed by the outlet mouth 5 of the hair dryer, is indicated in its entirety with reference numeral 1. For example, the flow rate and temperature can be adjusted according to four different modes, and the adjustments set can be indicated by a light display 12 with which the hair dryer is provided.

Furthermore, according to the invention, the hair dryer 1 is provided with a control element 6, in this embodiment a magnetometer sensor to be addressed hereinafter.

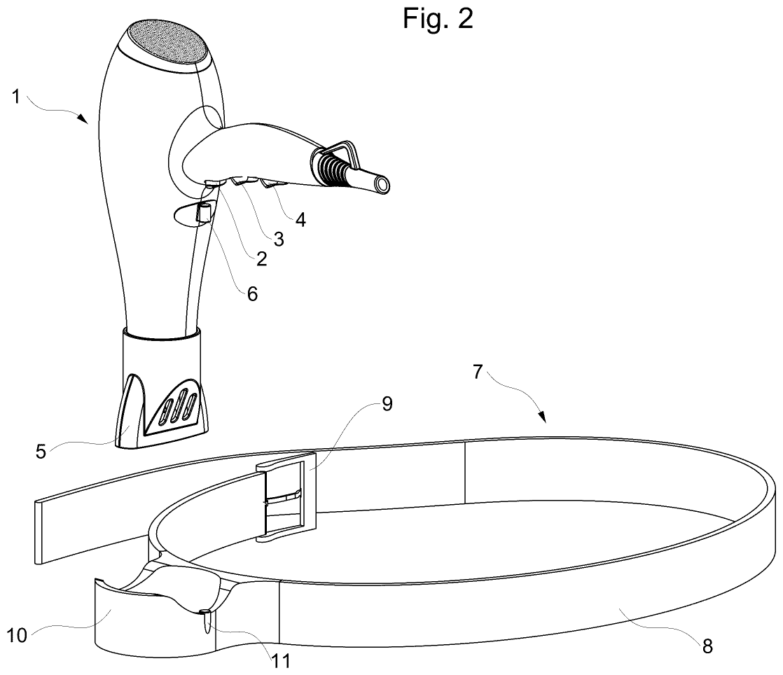

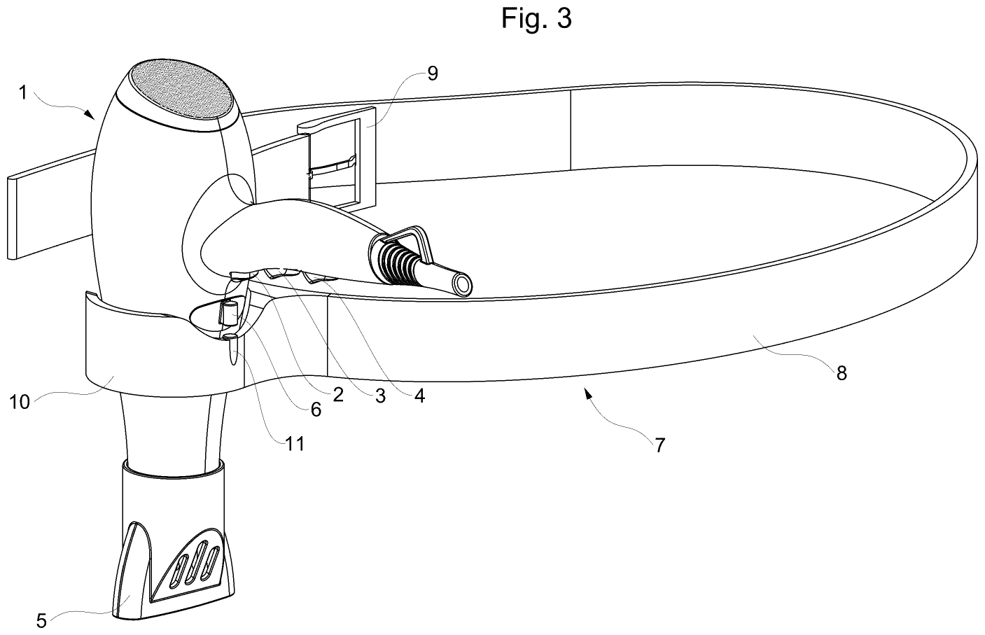

In FIG. 2, the hair dryer 1 is shown together with the wearable element 7 according to the invention, which consists of a belt 8 provided with an adjustment buckle 9 in this embodiment. The belt 8 further comprises a waist bag-like support 10 provided with the bottom wall and designed to house the hair dryer 1, as observable in FIG. 3, when not in use. Such support 10 includes a control element 11, a magnet in this embodiment, designed to interact with the control element 6 as mentioned hereinafter.

Furthermore, the hair dryer 1 may be provided with a CPU 13 designed to temporarily store the settings selected by the hairdresser using the buttons 3,4.

The magnetometer sensor 6 carried by the hair dryer 1 and the magnet 11 provided for on the support 10 of the belt 8 form a switch for switching the hair dryer 1 on and off. For example, in this embodiment, the magnetometer sensor 6 cooperates with the button for switching on and off 2 so that, when the magnetometer sensor 6 is arranged in proximity of the magnets 11 the hair dryer 1 turns off, while when the magnetometer sensor 6 is moved away from the magnet 11 the hair dryer 1 turns on automatically.

Now, herein described is an example of how the device according to the invention operates.

When treating the hair of a customer, when the hairdresser needs to use the hair dryer 1, he/she can comfortably remove it from the support 10 carried by the belt 8, set the hair drying program most suitable for the customer using the buttons 3,4 which will be stored by the CPU 13, and start the treatment.

When the hairdresser needs to carry out a treatment different from drying, he/she may comfortably place the hair dryer 1 in the support 10 of the belt 8 by approaching the control element 6 to the control element 11 so as to automatically switch the hair dryer 1 off. When the hairdresser needs to use the hair dryer 1 again, all he/she needs to do is remove it from the support 10 by moving the control element 6 away from the control element 11. In this manner, the hair dryer 1 turns on automatically at the same drying settings prior to turning off stored by the CPU 13.

Lastly, it should be observed that the device according to the invention can be advantageously used not only for professionals by hair salon operators, but also for personal use directly by the users.

Obviously, the construction details and the embodiments may widely vary with respect to what has been described and illustrated, without departing from the scope of protection of the present invention as described in the claims that follow. Therefore, for example, the general conformation and/or positioning of the support 10 and/or of the control elements 6, 11 could be different from the ones shown in the drawings.

1. Device for the automatic control of a hair dryer, said device comprising a wearable element provided with a support for the removable engagement with the hair dryer,
a first control element which can be coupled with said wearable element, and a second control element which can be coupled with said hair dryer,
said second control element being designed to switch said hair dryer off when arranged in proximity of said first control element, and to switch said hair dryer on when arranged away from said first control element, said wearable element comprising a belt provided with an adjustment buckle and said support comprising a waist bag carried by said belt.

2. Device according to claim 1, wherein said first control element is a magnet and said second control element is a magnetometer sensor.

3. (canceled)

4. Device according to claim 1, wherein said hair dryer comprises a pair of buttons for setting a hair drying program by adjusting respectively the flow and temperature of the air dispensed by the hair dryer, and a CPU designed to store the set drying program and to maintain such program each time the hair dryer is switched off and on.

5. Device according to claim 1, wherein said first control element is a magnetometer sensor and said second control element is a magnet.
